(19) United States
(12) Patent Application Publication
(10) Pub. No.: US 2023/0395612 A1
(43) Pub. Date: Dec. 7, 2023

(54) DISPLAY PANEL AND DISPLAY DEVICE

(71) Applicant: WUHAN TIANMA MICRO-ELECTRONICS CO., LTD., Wuhan (CN)

(72) Inventor: Fei LI, Wuhan (CN)

(73) Assignee: WUHAN TIANMA MICRO-ELECTRONICS CO., LTD., Wuhan (CN)

(21) Appl. No.: 18/453,780

(22) Filed: Aug. 22, 2023

(30) Foreign Application Priority Data
Jan. 18, 2023 (CN) 202310090123.8

(51) Int. Cl. H01L 27/12; G09G 3/32; G06F 3/041

(52) U.S. Cl. CPC H01L 27/124; G09G 3/32; G06F 3/0412; G09G 2300/0842; G09G 2354/00; G09G 2310/08

(57) ABSTRACT

A display panel and a display device are provided. The display panel includes pixels and first signal lines electrically connected to the pixels, wirings, and a shielding part. The pixels, the first signal lines, and at least part of one wiring are located in a display region. The wirings include first and second wirings, one first wiring is electrically connected to one first signal line, and the second wiring is insulated from the first wiring, one second wiring has a fracture end located in the display region, and one first wiring is located on a side of the fracture end away from one of the at least one second wiring. In a direction perpendicular to a plane of the display panel, the shielding part is located at a side of the wirings close to a light-exiting side of the display panel, and the shielding part overlaps with the fracture end.

### CROSS-REFERENCE TO RELATED APPLICATIONS

The present application claims priority to Chinese Patent Application No. 202310090123.8, filed on Jan. 18, 2023, the content of which is incorporated herein by reference in its entirety.

### TECHNICAL FIELD

The present disclosure relates to the field of display technologies, and in particular, to a display panel and a display device.

### BACKGROUND

With continuous development of science and technology, more and more display devices are widely used in people's daily life and work and become an indispensable and important tool for people today. Moreover, with continuous development of display technology, consumers' requirements for displays have been continuously increased, and various types of displays have been developed, such as liquid crystal display, organic light-emitting display and other display technologies. On this basis, three-dimension (3D) display, touch display, curved surface display, ultra-high-resolution display, high-frequency display and other technologies are also emerging.

At present, the display panel has the problems of large border width and uneven light-dark degrees of different positions in the display panel when the display panel is in a screen off state.

### SUMMARY

In one aspect, embodiments of the present disclosure provide a display panel. The display panel has a display region and includes pixels located in the display region, first signal lines located in the display region and electrically connected to the pixels, wirings, and at least one shielding part. At least part of one of the wirings is located in the display region, the wirings include at least one first wiring and at least one second wiring, one of the at least one first wiring is electrically connected to one of the first signal lines, and each of the at least one second wiring is insulated from the at least one first wiring. One of the at least one second wiring has a fracture end located in the display region, and one of the at least one first wiring is located on a side of the fracture end away from one of the at least one second wiring. In a direction perpendicular to a plane of the display panel, the at least one shielding part is located at a side of the wirings close to a light-exiting side of the display panel, and one of the at least one shielding part overlaps with the fracture end.

In another aspect, some embodiments of the present disclosure provide a display device including a display panel. The display panel has a display region and includes pixels located in the display region, first signal lines located in the display region and electrically connected to the pixels, wirings, and at least one shielding part. At least part of one of the wirings is located in the display region, the wirings include at least one first wiring and at least one second wiring, one of the at least one first wiring is electrically connected to one of the first signal lines, and each of the at least one second wiring is insulated from the at least one first wiring. One of the at least one second wiring has a fracture end located in the display region, and one of the at least one first wiring is located on a side of the fracture end away from one of the at least one second wiring. In a direction perpendicular to a plane of the display panel, the at least one shielding part is located at a side of the wirings close to a light-exiting side of the display panel, and one of the at least one shielding part overlaps with the fracture end.

### BRIEF DESCRIPTION OF DRAWINGS

In order to more clearly illustrate technical solutions of embodiments of the present disclosure, the accompanying drawings used in the embodiments are briefly described below. The drawings described below are merely a part of the embodiments of the present disclosure. Based on these drawings, those skilled in the art can obtain other drawings.

FIG. 1 is a schematic top view of a display panel according to an embodiment of the present disclosure;

FIG. 2 is an equivalent circuit diagram of a pixel according to an embodiment of the present disclosure;

FIG. 3 is a schematic operation timing diagram of a pixel driving circuit according to an embodiment of the present disclosure;

FIG. 4 is a schematic enlargement diagram of a first wiring, a second wiring and a first signal line according to an embodiment of the present disclosure;

FIG. 5 is a schematic diagram of a section of the first wiring, the second wiring and the first signal line in FIG. 4 along BB′;

FIG. 6 is a schematic enlargement diagram of a A first wiring, a second wiring and a first signal line according to an embodiment of the present disclosure;

FIG. 7 is a schematic partial enlargement diagram of a display region according to an embodiment of the present disclosure;

FIG. 8 is a layout corresponding to the pixel driving circuit shown in FIG. 2;

FIG. 9 is another schematic enlargement diagram of a A first wiring, a second wiring and a first signal line according to an embodiment of the present disclosure;

FIG. 10 is a schematic enlargement diagram of a A first wiring, a B first wiring and a first signal line according to an embodiment of the present disclosure;

FIG. 11 is a schematic partial enlargement diagram of the first region in FIG. 1;

FIG. 12 is another schematic partial enlargement diagram of the first region in FIG. 1;

FIG. 13 is a schematic partial enlargement diagram of the second region in FIG. 1;

FIG. 14 is another schematic partial enlargement diagram of the second region in FIG. 1;

FIG. 15 is another schematic partial enlargement diagram of the first region in FIG. 1; and

FIG. 16 is a schematic diagram of a display device according to an embodiment of the present disclosure.

### DESCRIPTION OF EMBODIMENTS

In order to better understand technical solutions of the present disclosure, the embodiments of the present disclosure are described in detail with reference to the drawings.

It should be clear that the described embodiments are merely part of the embodiments of the present disclosure rather than all of the embodiments. All other embodiments obtained by those skilled in the art shall fall into the protection scope of the present disclosure.

The terms used in the embodiments of the present disclosure are merely describing exemplary embodiments and not intended to limit the present disclosure. Unless otherwise noted in the context, the expressions “a”, “an”, “the” and “said” in singular form in the embodiments and appended claims of the present disclosure are also intended to represent a plural form.

It should be understood that the term “and/or” used in the present disclosure describes an association relationship for describing associated objects and represents that three relationships may exist. For example, A and/or B may represent the following three cases: A alone, both A and B, and B alone. The character generally indicates an “or” relationship between the associated objects.

It should be understood that although the terms first, second, third and the like may be used to describe the wiring in the embodiments of the present disclosure, these wiring should not be limited to these terms. These terms are only used to distinguish wirings from each other. For example, without departing from the scope of embodiments of the present disclosure, the first wiring may also be called the second wiring, similarly, the second wiring may also be called the first wiring.

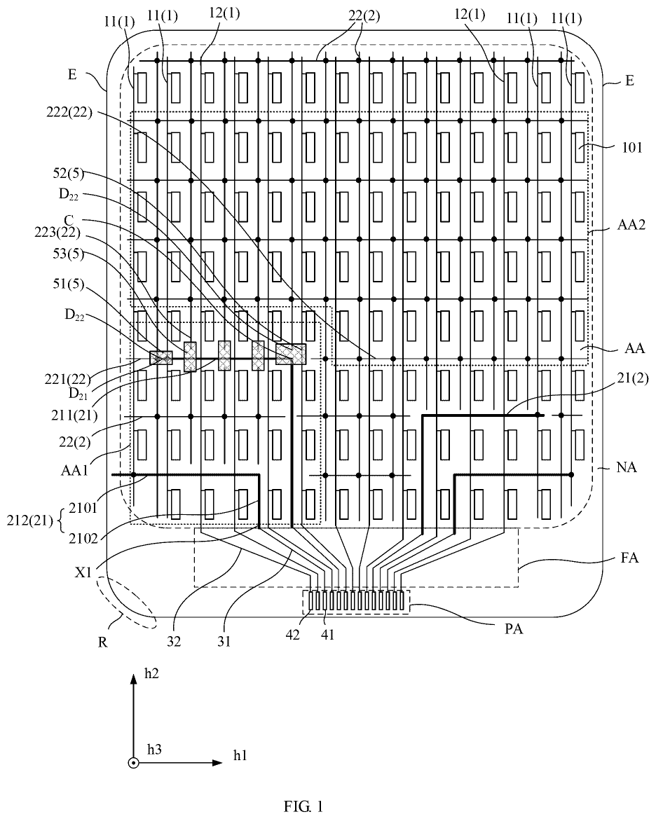

Embodiments of the present disclosure provides a display panel, as shown in FIG. 1, which is a schematic top view of a display panel according to an embodiment of the present disclosure. The display panel includes a display region AA and a non-display region NA. In some embodiments, the non-display region NA at least partially surrounds the display region AA. The display region AA includes multiple pixels.

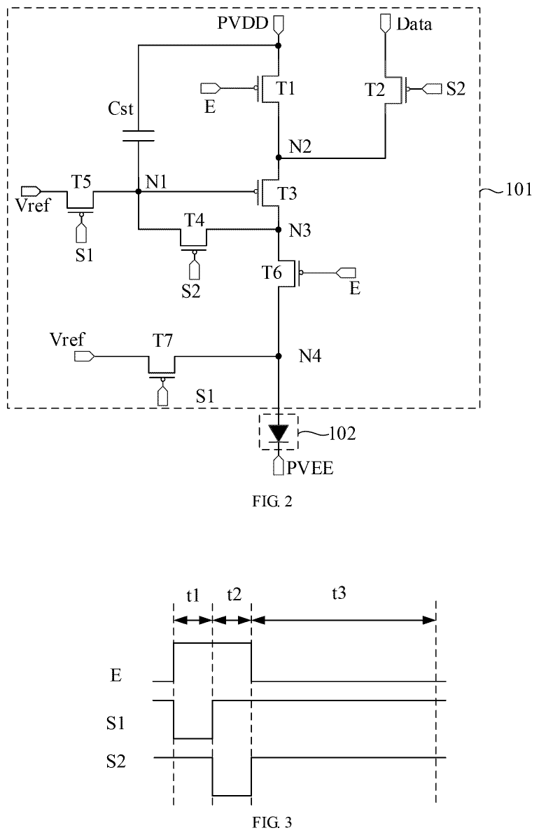

In some embodiments, as shown in FIG. 2, which is an equivalent circuit diagram of a pixel according to an embodiment of the present disclosure. The pixel includes a pixel driving circuit 101 and a light-emitting element 102 that are electrically connected to each other. The pixel driving circuit 101 includes a first transistor T1, a second transistor T2, a third transistor T3, a fourth transistor T4, a fifth transistor T5, a sixth transistor T6, a seventh transistor T7, and a storage capacitor Cst. As shown in FIG. 2, a control terminal of the third transistor T3 is electrically connected to a first node N1, a first terminal of the third transistor T3 is electrically connected to a second node N2, and a second terminal of the third transistor T3 is electrically connected to a third node N3. A control terminal of the first transistor T1 is electrically connected to a light-emitting control signal line E, and a first terminal of the first transistor T1 is electrically connected to a first power supply voltage line PVDD. A control terminal of the second transistor T2 is electrically connected to a second scanning line S2, and a first terminal of the second transistor T2 is electrically connected to a data line Data. A second terminal of the first transistor T1 and a second terminal of the second transistor T2 are electrically connected to the second node N2. A control terminal of the fourth transistor T4 is electrically connected to the second scanning line S2, a first terminal of the fourth transistor T4 is electrically connected to the third node N3, and a second terminal of the fourth transistor T4 is electrically connected to the first node N1. A control terminal of the fifth transistor T5 is electrically connected to a first scan line S1, a first terminal of the fifth transistor T5 is electrically connected to a reference voltage signal line Vref, a second terminal of the fifth transistor T5 is electrically connected to the first node N1. A control terminal of the sixth transistor T6 is electrically connected to the light-emitting control signal line E, a first terminal of the sixth transistor T6 is electrically connected to the third node N3, and a second terminal of the sixth transistor T6 is electrically connected to the fourth node N4. A control terminal of the seventh transistor T7 is electrically connected to the first scan line S1, and a first terminal of the seventh transistor T7 is electrically connected to the reference voltage signal line Vref, a second terminal of the seventh transistor T7 is electrically connected to the fourth node N4. A first electrode of the light-emitting element 102 is electrically connected to the fourth node N4, and a second electrode of the light-emitting element 102 is electrically connected to a second power supply voltage line PVEE. A first plate of the storage capacitor Cst is electrically connected to the first power supply voltage line PVDD, and a second plate of the storage capacitor Cst is electrically connected to the first node N1.

When the pixel driving circuit 101 operates, as shown in FIG. 2 and FIG. 3, FIG. 3 is a schematic operation timing diagram of a pixel driving circuit according to an embodiment of the present disclosure. The operation process of the pixel driving circuit includes a reset phase t1, a charging phase t2, and a light-emitting phase t3. During the reset phase t1, the first scan line S1 controls the fifth transistor T5 and the seventh transistor T7 to be turned on, a reference voltage provided by the reference voltage signal line Vref resets the first node N1 and the fourth node N4 through the fifth transistor T5 and the seventh transistor T7 respectively. During the charging phase t2, the second scan line S2 controls the second transistor T2 and the fourth transistor T4 to be turned on, and a data voltage Via, provided by the data line Data is written to the second node N2 through the second transistor T2. At this stage, the third transistor T3 is turned on. A potential of the first node N1 changes continuously until the potential I'm of the first node N1 changes to V_{N1}=V_{data}−|Vₜₕ|, V_{data} is the data voltage provided by the data line Data, and Vₜₕ is a threshold voltage of the third transistor T3. During the light-emitting phase t3, the first transistor T1, the sixth transistor T6 and the third transistor T3 are turned on, and the light-emitting element 102 electrically connected to the pixel driving circuit 101 is lightened.

The fifth transistor T5 and the seventh transistor T7 shown in FIG. 2 are electrically connected to the reference voltage signal line Vref, that is, the same reference voltage is configured to reset the first node N1 and the fourth node N4. In embodiments of the present disclosure, different reference voltages may be configured to reset the first node N1 and the fourth node N4, respectively. In some embodiments, the fifth transistor T5 is electrically connected to the first reference voltage signal line, the seventh transistor T7 is electrically connected to the second reference voltage signal line. The reference voltage provided by the first reference voltage signal line and the reference voltage provided by the second reference voltage signal line are different (for example, an amplitude of the reference voltage provided by the first reference voltage signal line and an amplitude of the reference voltage provided by the second reference voltage signal line are different).

As shown in FIG. 1, multiple signal lines 1 are provided in the display region AA. The signal line 1 is electrically connected to the pixel driving circuit 101. In some embodiments, the signal line 1 may be configured to transmit the data voltage required for the operation of the pixel driving circuit 101. That is, the signal line 1 includes the above data line Data.

As shown in FIG. 1, multiple signal lines 1 are arranged along a first direction h1, and the signal line 1 extends along a second direction h2. The first direction h1 and the second direction h2 intersect each other. In some embodiments, FIG. 1 shows that the first direction h1 is perpendicular to the second direction h2.

In embodiments of the present disclosure, the signal line 1 includes a first signal line 11 and a second signal line 12. The first signal line 11 is located on a side of the second signal line 12 close to an edge E of the display panel.

As shown in FIG. 1, the display panel 100 further includes wirings 2, which includes a first wiring 21 and a second wiring 22. At least part of the first wiring 21 is located in the display region AA, and at least part of the second wiring 22 is also located in the display region AA. The first wiring 21 is electrically connected to the first signal line 11. In some embodiments, as shown in FIG. 1, the first wiring 21 includes a first end X1 close to the non-display region NA. Along the first direction h1, the first end X1 is located on a side of the first signal line 11 close to the center of the display region AA.

In some embodiments of the present disclosure, as shown in FIG. 1, the first wiring 21 may include a first connecting sub-line 2101 and a second connecting sub-line 2102 electrically connected to each other, and an extension direction of the first connecting sub-line 2101 and an extension direction of the second connecting sub-line 2102 intersect each other. FIG. 1 shows that the first connecting sub-line 2101 extends along the first direction h1, and the second connecting sub-line 2102 extends along the second direction h2. As shown in FIG. 1, the second connecting sub-line 2102 is located at the side of the first signal line 11 close to the center of the display region AA. The end of the second connecting sub-line 2102 close to the non-display region NA is the first end X1.

In some embodiments, as shown in FIG. 1, the non-display region NA includes a fan-out region FA and a pin region PA. A first fan-out line 31 and a second fan-out line 32 are provided in the fan-out region FA. A first pin 41 and a second pin 42 are provided in the pin region PA. The first fan-out line 31 is electrically connected to the first wiring 21 and the first pin 41. The second fan-out line 32 is electrically connected to the second signal line 12 and the second pin 42. When the display panel operates, the signal transmitted by the first pin 41 is transmitted to the first wiring 21 through the first fan-out line 31 and is transmitted to the first signal line 11 through the first wiring 21. The signal transmitted by the second pin 42 is transmitted to the second signal line 12 through the second fan-out line 32. In some embodiments, the first pin 41 and the second pin 42 may be configured to transmit data voltage.

In the embodiments of the present disclosure, it is provided the first wiring 21 electrically connected to the first signal line 11, and at least part of the first wiring 21 is located in the display region AA, and the first end X1 of the first wiring 21 close to the non-display region NA is located at the side of the first signal line 11 close to the center of the display region AA, so that the first fan-out line 31 electrically connected to the first signal line 11 can be led out from the side of the first signal line 11 close to the center of the display region AA, and it is not necessary to make the first fan-out line 31 be led out from the end of the first signal line 11 close to the non-display region NA, therefore, an angle between the first fan-out line 31 and the second direction h2 can be reduced, that is, a tilt angle of the first fan-out line 31 relative to the second direction h2 can be reduced, and a width of the fan-out region FA in the second direction h2 can be reduced while ensuring good insulation of different fan-out lines.

In the embodiments of the present disclosure, the second wiring 22 is insulated from the first wiring 21, so that consistency of ambient light reflection at the region with the first wiring 21 and the region without the first wiring 21 in the display region AA can be improved, thereby improving a display effect of the display panel.

In some embodiments of the present the present disclosure, the first power supply voltage, the second power supply voltage and the reference voltage required for the operation of different pixel driving circuits 101 may be the same. That is, the first power supply voltage transmitted by the first power supply voltage line PVDD, the second power supply voltage transmitted by the second power supply voltage line PVEE, and the reference voltage transmitted by the reference voltage signal line Vref may be a common voltage shared by multiple pixel driving circuits 101.

In some embodiments, the second wiring 22 may be floating, that is, the second wiring 22 may not transmit any electrical signals. In some embodiments of the present disclosure, the second wiring 22 may transmit a common voltage, which includes any one of the first power supply voltage, the second power supply voltage and the reference voltage. In this way, the voltage drop of the common voltage can be reduced and the brightness consistency of each pixel can be improved.

In some embodiments of the present disclosure, the second wiring 22 may be arranged in the same layer as at least part of the first wiring 21.

As shown in FIG. 1, a fracture end D₂₂ of at least one of the second wirings 22 is located in the display region AA, and one of the first wirings 21 is located at a side of the fracture end D₂₂ of the second wiring 22 away from the second wiring 22. That is, the first wiring 21 and the second wiring 22 may be opposite to each other.

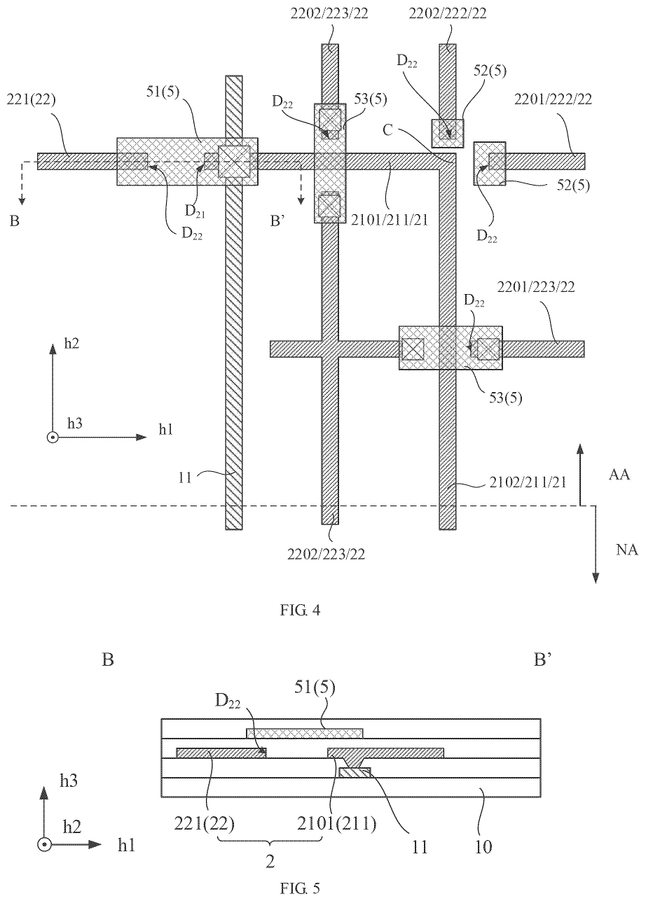

As shown in FIG. 1, the display panel includes a shielding part 5. Referring to FIG. 4 and FIG. 5, FIG. 4 is a schematic enlargement diagram of the first wiring 21, the second wiring 22 and the first signal line 11 according to an embodiment of the present disclosure, FIG. 5 is a schematic diagram of a section of the first wiring 21, the second wiring 22 and the first signal line 11 in FIG. 4 along BB′. In the direction h3 perpendicular to the plane of the display panel, the shielding part 5 is located at the side of the wiring 2 close to the light-exiting side of the display panel, and the shielding part 5 overlaps with the fracture end D₂₂ of the second wiring 22. In some embodiments, as shown in FIG. 4 and FIG. 5, the first wiring 21 may be arranged in a different layer from the first signal line 11 electrically connected to the first wiring 21, and the first wiring 21 is electrically connected to the first signal line 11 through a via. The first wiring may be arranged in a layer. As shown in FIG. 5, the display panel further includes a substrate 10. The first signal line 11 is located on one side of the substrate 10, and the first wiring 21 and the second wiring 22 are located at the side of the first signal line 11 away from the substrate 10. The shielding section 5 is located at the side of the first wiring 21 away from the first signal line 11.

In the display panel provided by the embodiments of the present disclosure, the width of the fan-out region FA can be reduced by providing the first wiring 21 electrically connected to the first signal line 11 and making at least part of the first wiring 21 be located in the display region AA.

Moreover, in the embodiments of the present disclosure, consistency of ambient light reflection at different positions in the display region AA can be improved by providing the second wiring 22 which is arranged in the same layer as at least part of the first wiring 21 and is insulated from the first wiring 21.

In addition, in embodiments of the present disclosure, the shielding part 5 is provided, in the direction h3 perpendicular to a plane of the display panel, the shielding part 5 is located on a side of the wirings close to the light-exiting side of the display panel, and the shielding part 5 overlaps with the fracture end D₂₂ of the second wiring 22, in this way, it is avoided visibility of the fracture end D₂₂ of the second wiring 22 when the display panel is in a screen off state caused by different reflection of the ambient light at the fracture end D₂₂ of the second wiring 22 and other positions other than the fracture end, thereby avoiding the problem of inconsistent visual effects at various positions in the display region AA when the display panel is in the screen off state. The screen off state refers to the state that the pixels in the display panel are not lightened.

In some embodiments, as shown in FIG. 1, the edge E of the display panel has a round corner R, and an extension line of the first signal line 11 passes through the round corner R. In the embodiments of the present disclosure, the first signal line 11 is electrically connected to the first wiring 21 in the display region AA, the number of fan-out lines corresponding to the round corner R can be reduced, which is beneficial to reduce a border width at the round corner R and improving the visual effect of the display panel.

In some embodiments, as shown in FIG. 1 and FIG. 4, the first wiring 21 includes a A first wiring 211, and at least one fracture end D₂₁ of the A first wiring 211 is located in the display region AA. The second wiring 22 includes a A second wiring 221, the fracture end D₂₂ of the A second wiring 221 and the fracture end D₂₁ of the A first wiring 211 are arranged oppositely.

As shown in FIG. 1 and FIG. 4, the shielding part 5 includes a first shielding part 51. In the direction h3 perpendicular to the plane of the display panel, the first shielding part 51 covers the fracture end D₂₁ the A first wiring 211 located in the display region AA and the fracture end D₂₂ of the A second wiring 221 located in the display region AA. In this way, at least two fracture ends can be covered by one first shielding part 51, therefore consistency of ambient light reflection at different positions in the display region can be improved when the display panel is in the screen off state, it is beneficial to reduce the number of the first shielding parts 51 in the display panel and ensure a high light transmittance of the display panel.

In some embodiments, the A first wiring 211 may include one or more fracture ends D₂₁ located in the display region AA. In a case that the A first wiring 211 includes multiple fracture ends D₂₁ located in the display region AA, multiple A second wirings 221 corresponding to different fracture ends D₂₁ may be provided in the display region AA. Accordingly, multiple first shielding parts 51 corresponding to different fracture ends D₂₁ may be provided in the display region AA.

Taking FIG. 4 as an example, in FIG. 4, the first connecting sub-line 2101 and the second connecting sub-line 2102 in the A first wiring 211 are arranged in the same layer, and the fracture end D₂₁ of the first connecting sub-line 2101 in the A first wiring 211 is located in the display region, and one A second wiring 221 corresponding to the fracture end D₂₁ is provided.

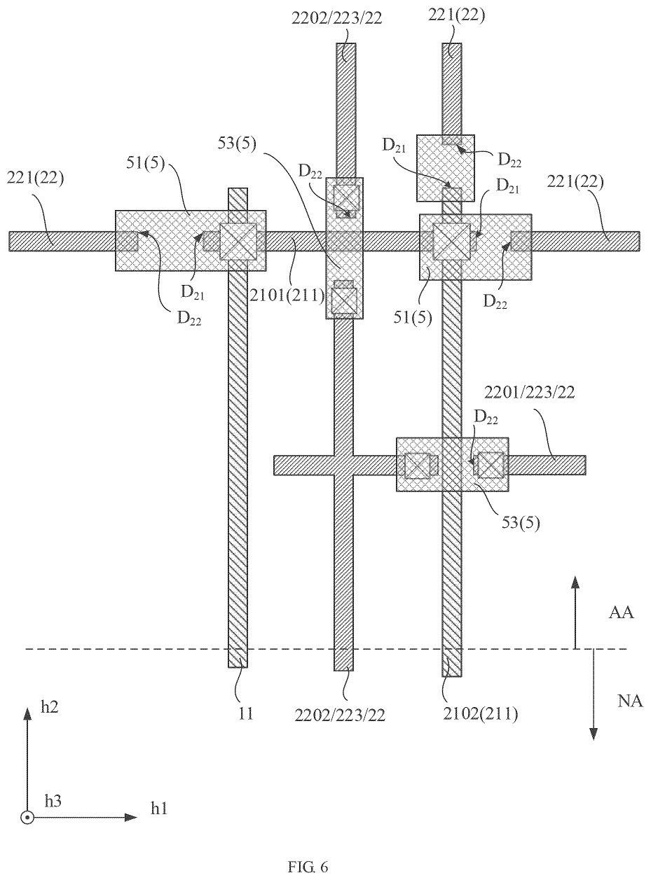

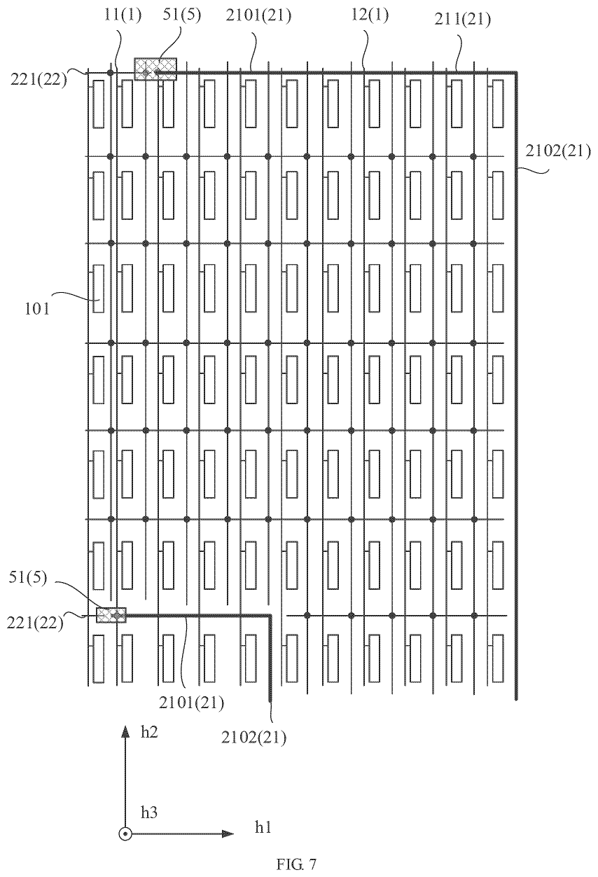

In some embodiments of the present disclosure, the first connecting sub-line 2101 and the second connecting sub-line 2102 in the A first wiring 211 may be arranged in different layers, as shown in FIG. 6. FIG. 6 is a schematic enlargement diagram of the A first wiring 211, the second wiring 22 and the first signal line 11 according to an embodiment of the present disclosure. The first connecting sub-line 2101 and the second connecting sub-line 2102 are arranged in different layers and are electrically connected through a via. The first connecting sub-line 2101 includes two fracture ends D₂₁ located in the display region AA, and the second connecting sub-line 2102 includes one fracture end D₂₁ located in the display region AA and one fracture end located in the non-display region NA. As shown in FIG. 6, corresponding to the A first wiring 211, it is provided two A second wirings 221 extending along the first direction h1 and opposite to the first connecting sub-line 2101 and one A second wiring 221 extending along the second direction h2 and opposite to the second connecting sub-line 2102. FIG. 6 shows three first shielding parts 51 corresponding to the three fracture ends D₂₂ of the three A second wirings 221.

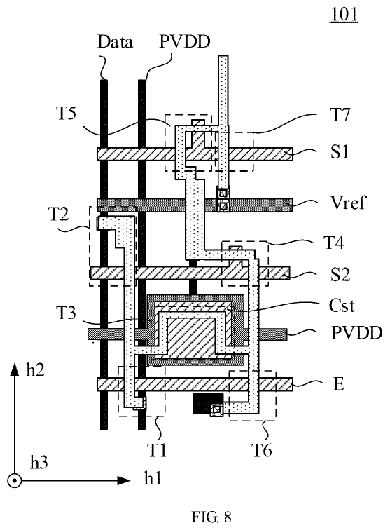

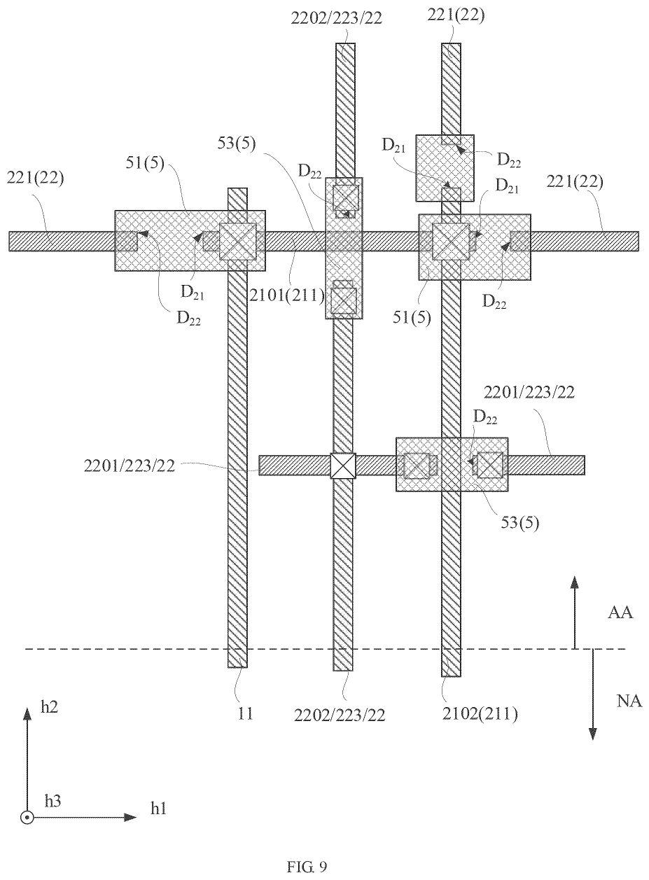

In some embodiments, the above first wiring 21 includes multiple A first wirings 211, and at least five pixel driving circuits 101 are arranged between two adjacent A first wirings 211. In the embodiments of the present disclosure, a case that at least five pixel driving circuits 101 are arranged between two adjacent A first wirings 211 means that at least five pixel driving circuits 101 arranged along the second direction h2 are arranged between the first connecting sub-lines 2101 of two adjacent A first wirings 211, and/or, at least five pixel driving circuits 101 arranged along the first direction h1 are arranged between the second connecting sub-lines 2102 of two adjacent A first wirings 211. As shown in FIG. 7, FIG. 7 is a schematic partial enlargement diagram of a display region according to an embodiment of the present disclosure. In FIG. 7, six pixel driving circuits 101 arranged along the second direction h2 are arranged between the first connecting sub-lines 2101 of two adjacent A first wirings 211, six pixel driving circuits 101 arranged along the first direction h1 are arranged between the second connecting sub-lines 2102 of two adjacent A first wirings 211. FIG. 8 is a layout corresponding to the pixel driving circuit shown in FIG. 2. As shown in FIG. 8, the left and right boundaries of each pixel driving circuit 101 in the first direction h1 may be defined by two adjacent data lines Data in the display panel, and the upper and lower boundaries of each pixel driving circuit 101 in the second direction h2 may be defined by two adjacent first scan lines S1 in the display panel.

In some embodiments of the present disclosure, the first wiring 21 includes multiple A first wirings 211, and at least five pixel driving circuits 101 are arranged between two adjacent A first wirings 211, so that the fracture ends of the A first wiring 211 in the display region AA are arranged more dispersedly, thereby improving dispersion uniformity of the A second wiring 221 and the first blocking section 51 corresponding to the fracture ends in the display region AA.

In some embodiments, as shown in FIG. 4, in a case that the first connecting sub-line 2101 and the second connecting sub-line 2102 in the first wiring 21 are arranged in the same layer, the first wiring 21 has a corner C. The corner C is a connection position between the first connecting sub-line 2101 and the second connecting sub-line 2102.

As shown in FIG. 1 and FIG. 4, the second wiring 22 includes a B second wiring 222, the B second wiring 222 is located at a side of the corner C of the B first wiring 212 away from the B first wiring 212. The existence of the B second wiring 222 can increase the coverage area of the second wiring 22, which is conducive to further improving the uniformity of reflected light intensity of the ambient light at various positions. When the B second wiring 222 transmits the common voltage, this arrangement can increase conduction paths of the common voltage, and then reduce the voltage drop of the common voltage, which is conducive to improving the display uniformity of pixels at various positions.

As shown in FIG. 1 and FIG. 4, the shielding part 5 includes a second shielding part 52. In the direction h3 perpendicular to the plane of the display panel 100, the second blocking part 52 covers the fracture end D₂₂ of the B second wiring 222 close to the corner C. In this way, the uniformity of reflected light intensity at different positions in the display region AA can be improved, it is avoided visibility of the fracture end D₂₂ of the B second wiring 222.

In some embodiments, as shown in FIG. 4, the second wiring 22 includes a first signal sub-line 2201 and a second signal sub-line 2202, an extension direction of the first signal sub-line 2201 and an extension direction of the second signal sub-line 2202 intersect each other. FIG. 4 shows that the first signal sub-line 2201 extends along the first direction h1 and the second signal sub-line 2202 extends along the second direction h2. The first signal sub-line 2201 of the second sub-wiring 222 is located at the side of the corner C away from the first connecting sub-line 2101, the second signal sub-line 2202 is located at the side of the corner C away from the second signal sub-line 2102.

In some embodiments, as shown in FIG. 4, at least two second shielding parts 52 are provided in the display region AA. One second shielding part 52 shields the fracture end D₂₂ of the first signal sub-line 2201 close to the A first wiring 211. The other second shielding part 52 shields the fracture end D₂₂ of the second signal sub-line 2202 close to the A first wiring 211.

Referring to FIG. 1, FIG. 4 and FIG. 6, the second wiring 22 further includes a C second wiring 223, a fracture end D₂₂ of the C second wiring 223 ends at a position of the first wiring 21 adjacent to the C second wiring 223 and at a non-corner of the first wiring 21. In some embodiments, as shown in FIG. 1, FIG. 4 and FIG. 6, the fracture end D₂₂ of the C second wiring 223 ends at the first connecting sub-line 2101 or the second connecting sub-line 2102. As shown in FIG. 4 and FIG. 6, the first wiring 21 is correspondingly provided with at least two C second wirings 223, one C second wiring 223 ends at the first connecting sub-line 2101, that is, an extension line of the one C second wiring 223 passes through the first connecting sub-line 2101. The other C second wiring 223 ends at the second connecting sub-line 2102, that is, an extension line of the other C second wiring 223 passes through the second connecting sub-line 2102.

With the C second wiring 223, the coverage area of the second wiring 22 can be increased, which is conducive to improving the uniformity of reflected light intensity of the ambient light at various positions. When the C second wiring 223 transmits the common voltage, such configuration can increase conduction paths of the common voltage, and then reduce the voltage drop of the common voltage, which is conducive to improving the display uniformity of pixels at various positions.

As shown in FIG. 1, FIG. 4 and FIG. 6, the shielding part 5 includes a third shielding part 53. In the direction h3 perpendicular to the plane of the display panel, the third blocking part 53 at least covers the fracture end D₂₂ of the C second wiring 223. The C second wiring 223 is provided to improve the uniformity of reflected light intensity at different positions in the display panel, the third shielding part 53 is provided to avoid visibility of the fracture end D₂₂ of the C second wiring 223.

In some embodiments, as shown in FIG. 1, FIG. 4 and FIG. 6, in a case that multiple C second wirings 223 correspond to the first wiring 21, multiple third shielding parts 53 are correspondingly provided in the display region AA provided with.

A layer position of the first wiring 21 and the second wiring 22 is not limited in the embodiments of the present disclosure. The configuration where the A second wiring 221 and the C second wiring 223 are located in a same layer shown in FIG. 6 is only a schematic diagram. FIG. 9 is another schematic enlargement diagram of a A first wiring, a second wiring and a first signal line according to an embodiment of the present disclosure. In some embodiments of the present disclosure, as shown in FIG. 9, the second connecting sub-line 2102, the A second wiring 221 extending along the second direction h2 and the C second wiring 223 extending along the second direction h2 are arranged in the same layer. In some embodiments, the second connecting sub-line 2102, the A second wiring 221 extending along the second direction h2, and the C second wiring 223 extending along the second direction h2 may be arranged in the same layer as the first signal line 11. The first connecting sub-line 2101, the A second wiring 221 extending along the first direction h1 and the C second wiring 223 extending along the first direction h1 may be arranged in the same layer. As shown in FIG. 9, the C second wiring 223 extending along the second direction h2 may be electrically connected to the C second wiring 223 extending along the first direction h1 through a via, and the C second wiring 223 extending along the second direction h2 and the C second wiring 223 extending along the first direction h1 intersect each other.

In some embodiments of the present disclosure, at most three pixel driving circuits 101 are arranged between two adjacent first wirings 21. In FIG. 1, two pixel driving circuits 101 along the second direction h2 are arranged between the first connecting sub-lines 2101 of two adjacent first wirings 21, and one pixel driving circuit 101 is arranged between the second connecting sub-lines 2102 of two adjacent first wirings 21. In some embodiments of the present disclosure, due to the limited space in the display region AA, at most one wiring 2 is arranged corresponding to each pixel driving circuit 101, that is, at most one first wiring 21 or one second wiring 22 is arranged for each pixel driving circuit 101. In some embodiments of the present disclosure, at most three pixel driving circuits 101 are arranged between two adjacent first wirings 21, which can reduce the number of the C second wirings 223 arranged between two adjacent first wirings 21, so as to reduce the number of the fracture ends D₂₂ of the C second wiring 223.

In some embodiments of the present disclosure, the third shielding part 53 includes conductive materials. As shown in FIG. 4, FIG. 6, and FIG. 9, in some embodiments of the present disclosure, the third shielding part 53 is electrically connected to two adjacent C second wirings 223 respectively located at two sides of the first wiring 21. In this way, when the C second wiring 223 transmits the common voltage such as the first power supply voltage, the second power supply voltage, the reference voltage, conduction paths of the common voltage can be increased, which can reduce the voltage drop of the common voltage and improving the brightness uniformity of pixels at different positions.

As shown in FIG. 1, the first wiring 21 includes at least one B first wiring 212, and two fracture ends D₂₁ of the B first wiring 212 are located in the non-display region NA. Compared with the layout that two fracture ends D₂₁ of the B first wiring 212 are located in the display region AA, in a case that the number of first wirings 21 is the same in the two arrangements, the existence of the B first wiring 212 can reduce the number of the fracture ends D 21 of the first wiring 21 in the display region AA, and can further improve a problem of uneven visual effects when the display panel is in the screen off state caused by the visibility of the fracture end of the first wiring 21.

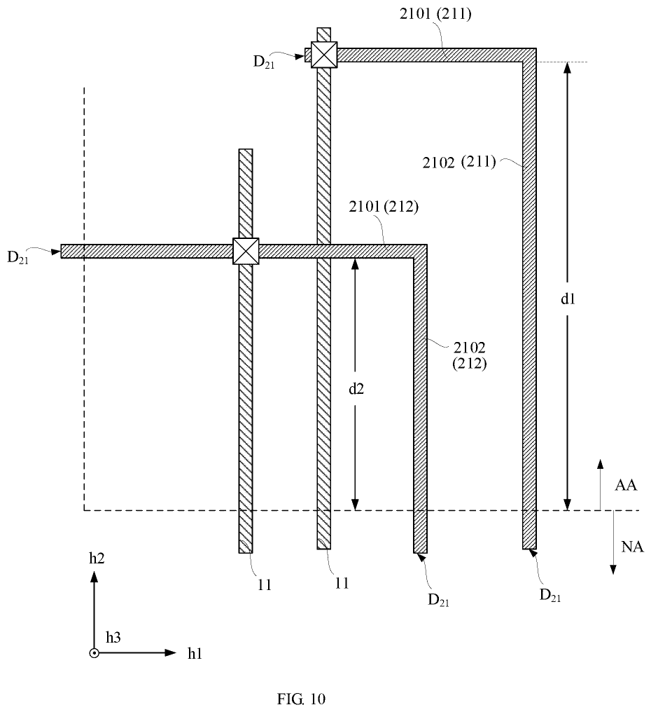

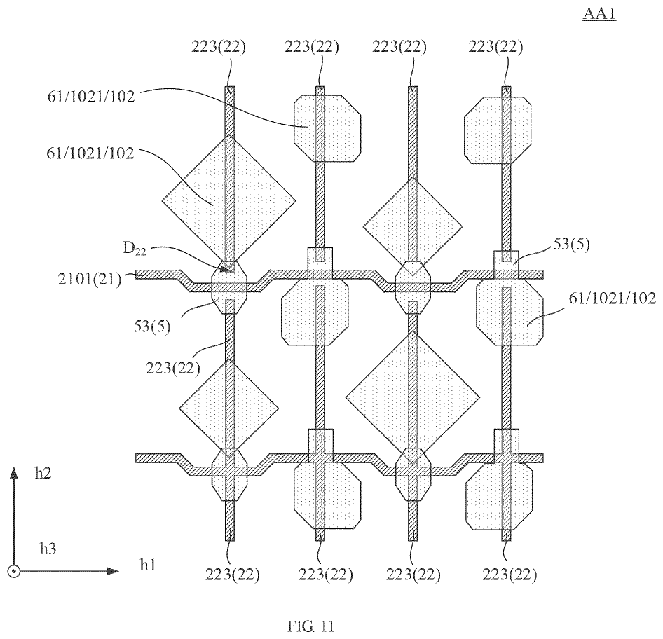

FIG. 10 is a schematic enlargement diagram of a A first wiring 211, a B first wiring 212 and a first signal line 11 according to an embodiment of the present disclosure. In some embodiments, referring to FIG. 10, in the B first wiring 212, the first connecting sub-line 2101 and the second connecting sub-line 2102 are arranged in the same layer, so as to avoid forming a fracture end at the side of the first connecting sub-line 2101 close to the second connecting sub-line 2102 and avoid forming a fracture end at the side of the second connecting sub-line 2102 close to the first connecting sub-line 2101. As shown in FIG. 10, the fracture end D 21 of the first connecting sub-line 2101 away from the second connecting sub-line 2102 is located in the non-display region NA, and the fracture end D₂₁ of the second connecting sub-line 2102 away from the first connecting sub-line 2101 is located in the non-display region NA.

In some embodiments of the present disclosure, as shown in FIG. 10, the first wiring 21 includes the A first wiring 211 and the B first wiring 212, and the fracture end D₂₁ of the A first wiring 211 is located in the display region AA, the fracture end D₂₁ of the B first wiring 212 is located in the non-display region NA. As shown in FIG. 10, a length d1 of the second connecting sub-line 2102 of the A first wiring 211 is greater than a length d2 of the second connecting sub-line 2102 of the B first wiring 212. In this way, compared with the layout that the fracture end of the B first wiring 212 is arranged in the display region AA, the first connecting sub-line 2101 of the B first wiring 212 is extended to the non-display region NA, which can not only reduce the number of fracture ends in the display region AA, but also compensate for the load difference caused by the different lengths of the second connecting sub-lines 2102 in the A first wiring 211 and the B first wiring 212.

In some embodiments of the present disclosure, multiple A first wirings 211 and multiple B first wirings 212 may be arranged in the display panel, and at least one B first wiring 212 is arranged between two adjacent A first wirings 211, and/or at least one A first wiring 211 is arranged between two adjacent B first wiring 212. In this way, the fracture ends of the A first wiring 211 located in the display region AA can be arranged dispersedly in the display region AA.

In some embodiments of the present disclosure, as shown in FIG. 1, the display region AA includes a first region AA1. FIG. 11 is a schematic partial enlargement diagram of the first region AA1 in FIG. 1. In some embodiments, as shown in FIG. 11, the light-emitting element 102 includes a first electrode 61. In some embodiments, the light-emitting element 102 may be electrically connected to the pixel driving circuit 101 through the first electrode 61.

In some embodiments of the present disclosure, the first electrode 61 and the shielding part 5 may be arranged in the same layer. In this way, the first electrode 61 and the shielding part 5 can be formed in the same process, and a preparation process of the display panel can be simplified. In addition, in some embodiments of the present disclosure, the first electrode 61 and the shielding part 5 are arranged in the same layer, so that the shielding part can avoid the layer where the pixel driving circuit 101 is located, and can avoid influence of the shielding part 5 on the pixel driving circuit 101. Compared with the layer where the pixel driving circuit 101 is located, the layer where the first electrode 61 is located has fewer structures. In some embodiments of the present disclosure, the shielding part 5 is arranged in the layer where the first electrode 61 is located, to reduce the interference of the shielding part on other structures. In FIG. 11, to clearly show the positions of the shielding section 5, the first electrode 61, the second wiring 22 and the first connecting sub-line 2101 in the first wiring 21, no other structure is drawn.

The display panel may be provided with a variety of light-emitting elements 102 configured to emit light of different colors. According to the light-emitting characteristics of each light-emitting element 102, the shapes and/or the areas of the first electrodes 61 of different light-emitting elements 102 may be different. The shape and/or the area of each first electrode 61 is not limited in the embodiments of the present disclosure.

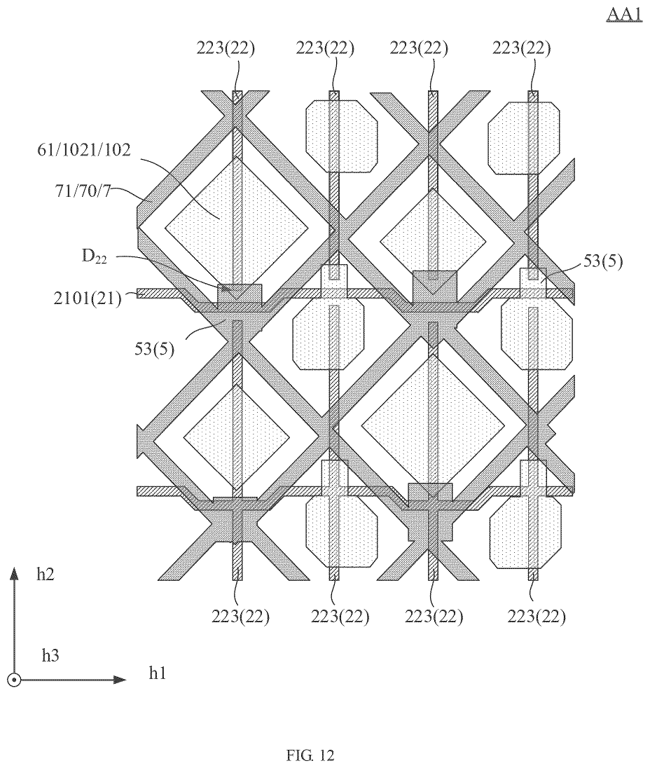

FIG. 12 is another schematic partial enlargement diagram of the first region AA1 in FIG. 1. In some embodiments of the present disclosure, as shown in FIG. 12, a touch electrode 7 may be arranged in the display panel to make the display panel have a touch function. In some embodiments of the present disclosure, the touch electrode 7 and the shielding part 5 may be arranged in the same layer, to simplify a preparation process of the display panel. In some embodiments of the present disclosure, the touch electrode 7 and the shielding part 5 are arranged in the same layer, so that the shielding part 5 can avoid the layer where the pixel driving circuit 101 is located, and can avoid influence of the shielding part 5 on the pixel driving circuit 101. Compared with the layer where the pixel driving circuit 101 is located, the layer where the touch electrode 7 is located has fewer structures. In some embodiments of the present disclosure, the shielding part 5 is arranged on the layer where the touch electrode 7 is located, to reduce the interference of the shielding part 5 on other structures. In FIG. 12, to clearly show the positions of the shielding section 5, the first electrode 61, the touch electrode 7, the second wiring 22 and the first connecting sub-line 2101 in the first wiring 21, no other structure is shown.

In some embodiments of the present disclosure, as shown in FIG. 11, the first electrode 61 and the shielding part 5 are arranged in the same layer. The fracture end D₂₂ of the second wiring 22 is located in the first region AA1. The light-emitting element 102 includes the first light-emitting sub-element 1021 located in the first region AA1. In the direction h3 perpendicular to the plane of the display panel, the first electrode 61 of the first light-emitting sub-element 1021 does not overlap with the fracture end D₂₂ of the second wiring 22, and the shielding part 5 is connected to the first electrode 61 of the first light-emitting sub-element 1021. Since the region where the fracture end D₂₂ is located is the region where the second wiring 22 ends, the layer where the second wiring 22 is located has a segment difference at this position. In some embodiments of the present disclosure, the first electrode 61 of the first light-emitting sub-element 1021 is arranged at a position different from a position of the fracture end D₂₂ of the second wiring 22, so that the flatness of the position of the first electrode 61 can be ensured, which is conducive to improving a preparation yield of the first light-emitting sub-element 1021 including the first electrode 61, and improving the light-emitting effect of the first light-emitting sub-element 1021.

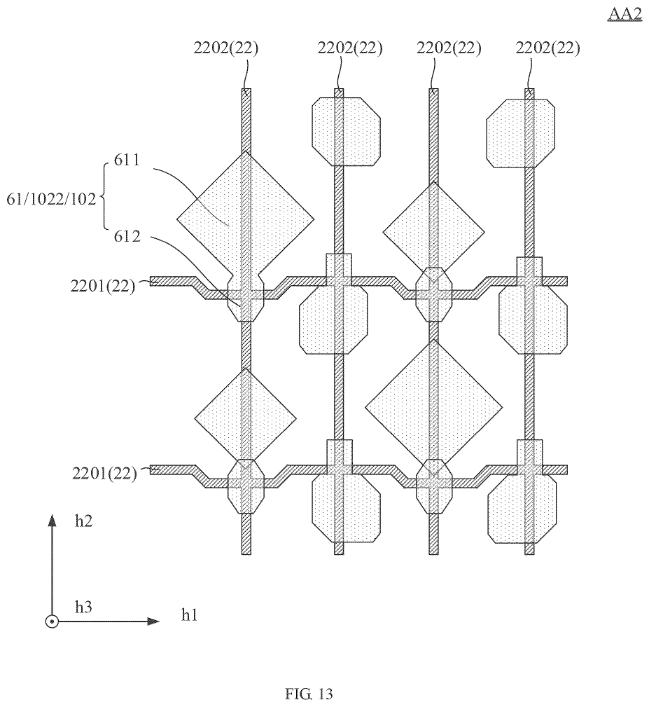

In some embodiments of the present disclosure, as shown in FIG. 1, the display region AA further includes a second region AA2. As shown in FIG. 13, FIG. 13 is a schematic partial enlargement diagram of the second region AA2 in FIG. 1. The second wiring 22 includes the first signal sub-line 2201 and the second signal sub-line 2202, and the first signal sub-line 2201 and the second signal sub-line 2202 intersect each other and are electrically connected to each other in the second region AA2.

As shown in FIG. 13, a second light-emitting sub-element 1022 is provided in the second region AA2. The first electrode 61 of the second light-emitting sub-element 1022 includes a body part 611 and a protrusion part 612. In the direction h3 perpendicular to a plane of the display panel, the protrusion part 612 overlaps with a position where the first signal sub-line 2201 and the second signal sub-line 2202 intersect each other.

In some embodiments of the present disclosure, referring to FIG. 11 and FIG. 13, the body part 611 and the first electrode 61 of the first sub-luminous element 1021 in the first area AA1 have a same shape and a same area, and the protrusion part 612 and the shielding part 5 in the first area AA1 have a same shape and a same area. In this way, it can ensure that, in the display region AA, the pattern distribution of the first electrode 61 in the first region AA1 with the first wiring 21 is as consistent as possible with the pattern distribution of the first electrode 61 in the second area. AA2 without the first wiring 21 and with the second wiring 22, which improves the consistency of the pattern distribution in different regions in the display region AA.

As shown in FIG. 12, the touch electrode 7 includes a first touch grid sub-line 71 located in the first region AA1. In the embodiments of the present disclosure, in the direction h3 perpendicular to the plane of the display panel, the first touch grid sub-line 71 does not overlap with the fracture end D 22 of the second wiring 22, and the shielding part 5 is connected to the first touch grid sub-line 71. Since the region where the fracture end D₂₂ is located is the region where the second wiring 22 ends, the layer where the second wiring 22 is located has a segment difference at this position. In some embodiments of the present disclosure, the first electrode 61 of the first touch grid sub-line 71 is arranged at a position different from a position of the fracture end D₂₂ of the second wiring 22, so that the flatness of the position of the first touch grid sub-line 71 can be ensured, which improves a preparation yield of the first touch grid sub-line 71.

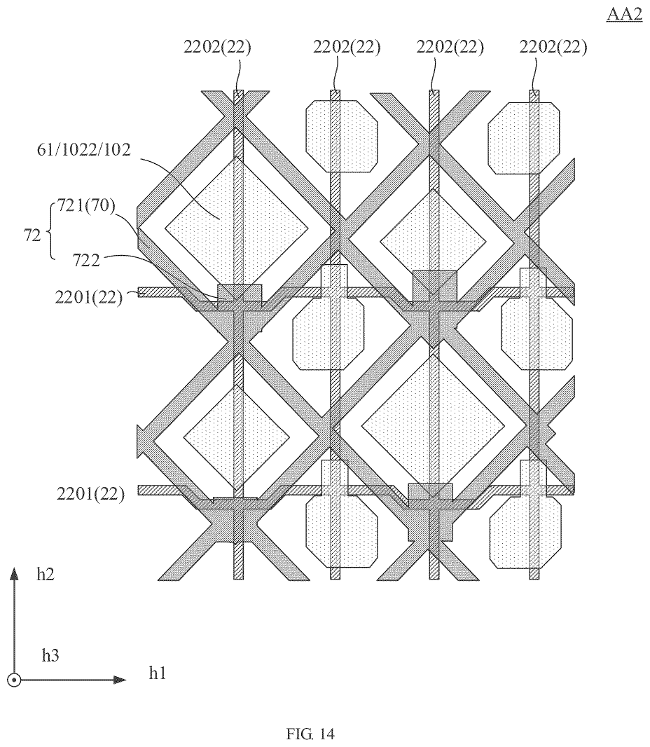

As shown in FIG. 1, the display region AA includes a second area AA2. FIG. 14 is another schematic partial enlargement diagram of the second region AA2 in FIG. 1. Referring to FIG. 14, in the second region AA2, the second wiring 22 includes the first signal sub-line 2201 and the second signal sub-line 2202, the first signal sub-line 2201 and the second signal sub-line 2202 intersect each other and are electrically connected to each other in the second region AA2. The second region AA2 includes a second touch grid sub-line 72. The second touch grid sub-line 72 includes a body part 721 and a protrusion part 722. In the direction h3 perpendicular to a plane of the display panel, the protrusion part 722 overlaps with a position where the first signal sub-line 2201 and the second signal sub-line 2202 intersect each other.

In some embodiments of the present disclosure, referring to FIG. 12 and FIG. 14, the body part 721 and the first touch grid sub-line 71 have a same shape and a same area, and the protrusion part 722 and the shielding part 5 have a same shape and a same area. In this way, it can ensure that, in the display region AA, the pattern distribution of the touch grid line in the first region AA1 with the first wiring 21 is as consistent as possible with the pattern distribution of touch grid line in the second area AA2 without the first wiring 21 and with the second wiring 22, which improves the consistency of the pattern distribution in different regions in the display region AA.

In some embodiments of the present disclosure, as shown in FIG. 12 and FIG. 14, the touch electrode 7 includes touch grid lines 70 and openings defined by the touch grid lines 70, and the opening at least partially exposes the light-emitting element 102. The touch grid line 70 includes conductive materials such as metal or graphene. In some embodiments of the present disclosure, the touch electrode 7 includes touch grid lines 70 and the opening at least partially exposes the light-emitting element 102, and the influence of the touch electrode 7 on the light emitted from the light-emitting element 102 is reduced, thereby improving the display effect of the display panel.

In some embodiments of the present disclosure, as shown in FIG. 12, in the direction h3 perpendicular to a plane of the display panel, the touch grid line 70 at least partially covers at least part of the first wiring 21. In this way, the touch grid line 70 can be configured to shield at least part of the first wiring 21, and the visibility of the first wiring 21 can be reduced.

In some embodiments of the present disclosure, as shown in FIG. 12, the width of the touch grid line 70 is greater than the width of the first wiring 21. In this way, the touch grid line 70 can shield the fracture end of the first wiring 21 as much as possible by adjusting the relative position between the touch grid line 70 and the first wiring 21, which is beneficial to reducing the area of the shielding part 5 and ensuring that the display panel has a high light transmittance.

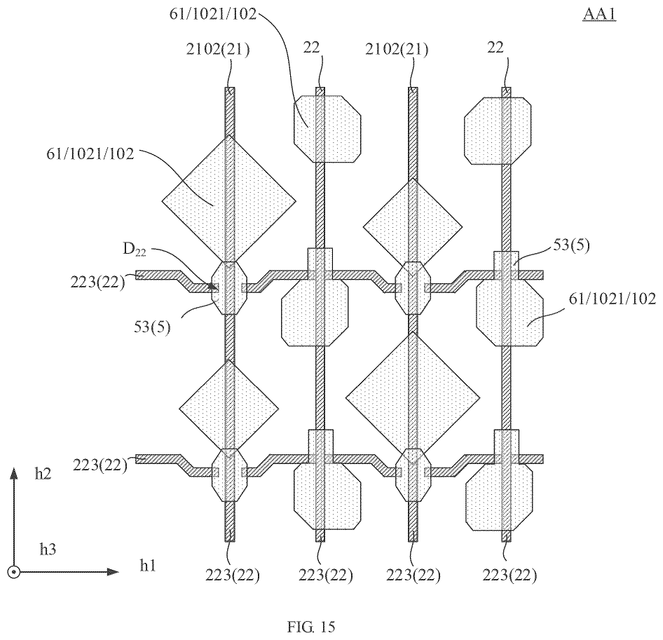

In some embodiments of the present disclosure, when arranging the first wiring 21 and the first electrode 61, in the direction h3 perpendicular to a plane of the display panel, the second connecting sub-line 2102 overlaps with a center of the first electrode 61, and/or the first connecting sub-line 2101 does not overlap with the first electrode 61. FIG. 11 shows that the first connecting sub-line 2101 does not overlap with the first electrode 61. FIG. 15 is another schematic partial enlargement diagram of the first region AA1 in FIG. 1. As shown in FIG. 15, the second connecting sub-line 2102 overlaps with the center of the first electrode 61. In this way, the first electrode 61 can be symmetrically arranged relative to the second connecting sub-line 2102, and the display effects observed from different angles of view can be similar, which improves the color deviation problem under different angles of view.

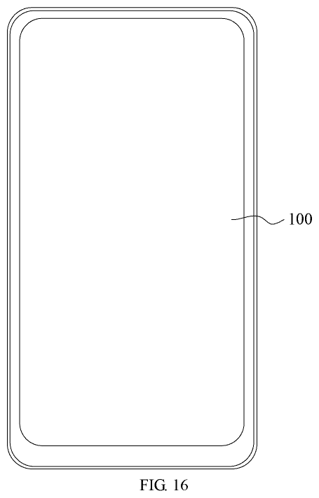

FIG. 16 is a schematic diagram of a display device according to an embodiment of the present disclosure. Some embodiments of the present disclosure also provide a display device, as shown in FIG. 16, the display device includes the above display panel 100. The structure of the display panel 100 has been described in detail in the above embodiments, which is not repeated herein. The display device shown in FIG. 16 is only a schematic illustration. The display device may be any electronic device with display function, such as a mobile phone, a tablet computer, a notebook computer, an electronic paper book, or a television.

The above illustrates some exemplary embodiments of the present disclosure and are not intended to limit the present disclosure. Any modification, equivalent replacement, or improvement made within the principle of the present disclosure should be included in the scope of the present disclosure.

What is claimed is:

1. A display panel, having a display region and comprising:
pixels located in the display region;
first signal lines located in the display region and electrically connected to the pixels;
wirings, wherein at least part of one of the wirings is located in the display region, the wirings comprise at least one first wiring and at least one second wiring, one of the at least one first wiring is electrically connected to one of the first signal lines, and each of the at least one second wiring is insulated from the at least one first wiring; one of the at least one second wiring has a fracture end located in the display region, and one of the at least one first wiring is located on a side of the fracture end away from one of the at least one second wiring; and
at least one shielding part, wherein in a direction perpendicular to a plane of the display panel, the at least one shielding part is located at a side of the wirings close to a light-exiting side of the display panel, and one of the at least one shielding part overlaps with the fracture end.

2. The display panel according to claim 1, wherein the at least one first wiring comprises at least one A first wiring, wherein a fracture end of one A first wiring of the at least one A first wiring is located in the display region;
the second wiring comprises a A second wiring, the fracture end of one the at least one A second wiring is opposite to the fracture end of the A first wiring; and
the at least one shielding part comprises a first shielding part, wherein in the direction perpendicular to the plane of the display panel, the first shielding part covers the fracture end of the A first wiring and the fracture end of the A second wiring.

3. The display panel according to claim 2, wherein each of the pixels comprises a pixel driving circuit and a light-emitting element that are electrically connected to each other; and
the at least one A first wiring comprises a plurality of A first wirings, and at least five pixel driving circuits of the pixels are arranged between two adjacent A first wirings of the plurality of A first wirings.

4. The display panel according to claim 2, wherein one of the at least one A first wiring has a corner;
the at least one second wiring further comprises a B second wiring located at a side of the corner away from one of the at least one A second wiring; and
the at least one shielding part further comprises a second shielding part, wherein in the direction perpendicular to the plane of the display panel, the second shielding part covers a fracture end of the B second wiring close to the A first wiring.

5. The display panel according to claim 2, wherein the at least one second wiring further comprises at least one C second wiring, a fracture end of one C second wiring of the at least one C second wiring ends at a position of one first wiring of the at least one first wiring adjacent to the C second wiring and at a non-corner of the one first wiring; and
the at least one shielding part further comprises a third shielding part, wherein in the direction perpendicular to the plane of the display panel, the third shielding part at least covers a fracture end of the C second wiring.

6. The display panel according to claim 5, wherein each of the pixels comprises a pixel driving circuit and a light-emitting element that are electrically connected to each other, and the at least one first wiring comprises a plurality of first wirings; and
at most three pixel driving circuits of the pixels are arranged between two adjacent first wirings of the plurality of first wirings.

7. The display panel according to claim 5, wherein the at least one C second wiring comprises a plurality of C second wirings, and the third shielding part is electrically connected to two adjacent C second wirings of the plurality of C second wirings that are respectively located at two sides of one of the at least one first wiring.

8. The display panel according to claim 1, further having a non-display region, wherein the at least one first wiring comprises at least one B first wiring, and two fracture ends of one of the at least one B first wiring are located in the non-display region.

9. The display panel according to claim 8, wherein one of the at least one B first wiring comprises a first connecting sub-line and a second connecting sub-line that are electrically connected to each other, wherein an extension direction of the first connecting sub-line and an extension direction of the second connecting sub-line intersect each other; and
the first connecting sub-line and the second connecting sub-line are arranged in a same layer, a fracture end of the first connecting sub-line away from the second connecting sub-line is located in the non-display region, and a fracture end of the second connecting sub-line away from the first connecting sub-line is located in the non-display region.

10. The display panel according to claim 9, wherein the at least one first wiring comprises a A first wiring, wherein a fracture end of the A first wiring is located in the display region;
the A first wiring comprises a first connecting sub-line and a second connecting sub-line that are electrically connected to each other, and an extension direction of the first connecting sub-line and an extension direction of the second connecting sub-line intersect each other;
a length of the second connecting sub-line of the A first wiring is greater than a length of the second connecting sub-line of the B first wiring;
a fracture end of the first connecting sub-line of the B first wiring is located in the non-display region; and
a fracture end of the first connecting sub-line of the A first wiring is located in the display region.

11. The display panel according to claim 8, wherein the at least one first wiring comprises a plurality of A first wirings, wherein a fracture end of one of the plurality of A first wirings is located in the display region;
the at least one B first wirings comprises a plurality of B first wirings; and
at least one of the plurality of B first wirings is arranged between two adjacent A first wirings of the plurality of A first wirings, and/or at least one A first wiring of the plurality of A first wirings is arranged between two adjacent B first wirings of the plurality of B first wirings.

12. The display panel according to claim 1, wherein each of the pixels comprises a pixel driving circuit and a light-emitting element that are electrically connected to each other, the light-emitting element comprises a first electrode, the first electrode and the at least one shielding part are arranged in a same layer; and/or
the display panel comprises a touch electrode, and the touch electrode and the at least one shielding part are arranged in a same layer.

13. The display panel according to claim 12, wherein the first electrode and the at least one shielding part are arranged in a same layer, the display region comprises a first region, and the fracture end of the one of the at least one second wiring is located in the first region; and
the light-emitting element comprises a first light-emitting sub-element located in the first region, wherein the first electrode of the first light-emitting sub-element does not overlap with the fracture end of the one of the at least one second wiring in the direction perpendicular to the plane of the display panel, and one of the at least one shielding part is connected to the first electrode of the first light-emitting sub-element.

14. The display panel according to claim 13, wherein the display region further comprises a second region, and the at least one second wiring comprises a first signal sub-line and a second signal sub-line, wherein the first signal sub-line and the second signal sub-line intersect each other and are electrically connected to each other in the second region; and
the light-emitting element comprises a second light-emitting sub-element located in the second region, wherein a first electrode of the second light-emitting sub-element comprises a body part and a protrusion part, wherein, in the direction perpendicular to the plane of the display panel, the protrusion part overlaps with a position where the first signal sub-line and the second signal sub-line intersect each other.

15. The display panel according to claim 12, wherein the touch electrode and the at least one shielding part are arranged in a same layer, the display region comprises a first region, and the fracture end of the second wiring is located in the first region; and
the touch electrode comprises a first touch grid sub-line located in the first region, wherein, in the direction perpendicular to the plane of the display panel, the first touch grid sub-line does not overlap with the fracture end of the second wiring, and the at least one shielding part is connected to the first touch grid sub-line.

16. The display panel according to claim 15, wherein the display region further comprises a second region, and the at least one second wiring comprises a first signal sub-line and a second signal sub-line, wherein the first signal sub-line and the second signal sub-line intersect each other and are electrically connected to each other in the second region; and
the touch electrode comprises a second touch grid sub-line located in the second region, wherein the second touch grid sub-line comprises a body part and a protrusion part, wherein, in the direction perpendicular to the plane of the display panel, the protrusion part of the second touch grid sub-line overlaps with a position where the first signal sub-line and the second signal sub-line intersect each other.

17. The display panel according to claim 12, wherein the touch electrode comprises touch grid lines and openings defined by the touch grid lines, wherein one of the openings at least partially exposes one light-emitting element of the light-emitting elements of the pixels, and one of the touch grid lines at least partially covers at least part of one of the at least one first wiring in the direction perpendicular to the plane of the display panel.

18. The display panel according to claim 17, wherein a width of one of the touch grid lines is greater than a width of one of the at least one first wiring.

19. The display panel according to claim 12, wherein one of the at least one first wiring comprises a first connecting sub-line and a second connecting sub-line that are electrically connected to each other, wherein an extension direction of the first connecting sub-line and an extension direction of the second connecting sub-line intersect each other; and
in the direction perpendicular to the plane of the display panel, the second connecting sub-line overlaps with a center of the first electrode, and/or the first connecting sub-line is staggered from the first electrode.

20. A display device comprising a display panel, wherein the display panel has a display region and comprises:
pixels located in the display region;
first signal lines located in the display region and electrically connected to the pixels;
wirings, wherein at least part of one of the wirings is located in the display region, the wirings comprise at least one first wiring and at least one second wiring, one of the at least one first wiring is electrically connected to one of the first signal lines, and each of the at least one second wiring is insulated from the at least one first wiring; one of the at least one second wiring has a fracture end located in the display region, and one of the at least one first wiring is located on a side of the fracture end away from one of the at least one second wiring; and
at least one shielding part, wherein in a direction perpendicular to a plane of the display panel, the at least one shielding part is located at a side of the wirings close to a light-exiting side of the display panel, and one of the at least one shielding part overlaps with the fracture end.
